(19) United States
(12) Patent Application Publication
(10) Pub. No.: US 2021/0375628 A1
(43) Pub. Date: Dec. 2, 2021

(54) MANUFACTURING METHOD FOR BONDED SUBSTRATE

(71) Applicant: Murata Manufacturing Co., Ltd., Nagaokakyo-shi (JP)

(72) Inventors: Ryunosuke Hino, Nagaokakyo-shi (JP); Yuzu Kishi, Nagaokakyo-shi (JP); Yutaka Kishimoto, Nagaokakyo-shi (JP)

(21) Appl. No.: 17/399,421

(22) Filed: Aug. 11, 2021

Related U.S. Application Data
(63) Continuation of application No. PCT/JP2020/009819, filed on Mar. 6, 2020.

(30) Foreign Application Priority Data
Apr. 8, 2019 (JP) 2019-073518

(51) Int. Cl. H01L 21/18; B81C 1/00

(52) U.S. Cl. CPC H01L 21/187; B81C 2201/0104; B81C 2203/038; B81C 1/0019

(57) ABSTRACT

A manufacturing method for a bonded substrate that includes preparing a first substrate having a surface with a projected portion in a central region of the surface, preparing a second substrate, and bonding the first substrate and the second substrate using the projected portion as a bonding surface to be bonded to the second substrate.

### CROSS REFERENCE TO RELATED APPLICATIONS

The present application is a continuation of International application No. PCT/JP2020/009819, filed Mar. 6, 2020, which claims priority to Japanese Patent Application No. 2019-073518, filed Apr. 8, 2019, the entire contents of each of which are incorporated herein by reference.

### FIELD OF THE INVENTION

The present invention relates to a manufacturing method for a bonded substrate in which a first substrate and a second substrate are bonded to each other.

### BACKGROUND OF THE INVENTION

Patent Document 1 discloses a method of bonding two substrates by placing those two substrates one above the other in a state free from being flexed or distorted with no internal stress remaining in both the substrates; attracting and holding a first substrate at least at a plurality of points on the first substrate; supporting the first substrate from a rear surface side to be deformed into a convex shape protruding toward a second substrate that is positioned to face the first substrate; bringing the first substrate into contact with the second substrate starting from a protruding area of the first substrate, the protruding area being positioned closest to the second substrate; and bringing the first substrate into contact with the second substrate gradually from the protruding area toward an adjacent area while cancelling the convex shape in a contact area between the first substrate and the second substrate, thus causing the first substrate and the second substrate to be closely placed one above the other.

Patent Document 2 discloses a method of bonding two substrates so as to prevent the generation of voids between those two substrates and to bond the two substrates with high positional accuracy. The method includes performing hydrophilization to attach water or an OH-containing substance to bonding surfaces of the first substrate and the second substrate; flexing the first substrate such that a central region of the bonding surface of the first substrate is protruded toward the second substrate relative to an outer peripheral region of the bonding surface of the first substrate; placing the bonding surface of the first substrate and the bonding surface of the second substrate to be positioned oppositely at their central regions; and entirely sticking the bonding surface of the first substrate and the bonding surface of the second substrate while a distance between an outer peripheral region of the first substrate and an outer peripheral region of the second substrate is reduced in a state in which the first substrate and the second substrate are oppositely placed with a certain distance held between the central regions thereof, wherein a distance between the first substrate and the second substrate is measured before or after the opposing of the bonding surfaces, and the distance between the outer peripheral region of the first substrate and the outer peripheral region of the second substrate is reduced.

Patent Document 3 discloses a method of, aiming to, when bonding two substrates, prevent the generation of voids between those two substrates, warping the two substrates to have convex portions with vacuum suction, bringing the convex portions into contact with each other, and then releasing the vacuum to make the two substrates closely contacted and entirely bonded to each other.

Patent Document 1: Japanese Unexamined Patent Application Publication No. 9-283392

Patent Document 2: International Publication No. 2017/155002

Patent Document 3: Japanese Unexamined Patent Application Publication No. 63-19807

### SUMMARY OF THE INVENTION

With the above-described manufacturing methods for the bonded substrate disclosed in Patent Documents 1 to 3, because the two substrates are bonded to each other in the state in which at least one of the two substrates is flexed to deform the central region into the convex shape, the bonding between the outer peripheral regions of the two substrates is difficult to perform appropriately, and voids are more likely to generate in the layered substrate after the bonding. Furthermore, because the substrate is flexed or warped, a structure of bonding equipment is complicated.

In consideration of the above-described situation, an object of the present invention is to provide a manufacturing method for a bonded substrate which can be implemented with a relatively simple structure of bonding equipment and which can suppress the generation of voids.

The present invention provides a manufacturing method for a bonded substrate, the manufacturing method including: preparing a first substrate having a surface with a projected portion in a central region of the surface; preparing a second substrate; and bonding the first substrate and the second substrate using the projected portion as a bonding surface to be bonded to the second substrate.

With the manufacturing method for the bonded substrate according to the present invention, the first substrate having the surface with the projected portion formed in the central region of the surface and the second substrate are prepared, and the first substrate and the second substrate are bonded while the surface of the first substrate, including the projected portion, is used as the bonding surface to be bonded to the second substrate. Therefore, when the bonding is started, the first substrate and the second substrate are first stuck to each other at a contact point between the projected portion in the central region of the bonding surface of the first substrate and a bonding surface of the second substrate, and those substrates are then bonded gradually toward a region around the projected portion. Hence voids are less likely to generate. Furthermore, since there is no necessity of flexing or warping the substrate in a bonding process unlike the related art, the bonded substrate can be manufactured by using a universal bonding apparatus.

### BRIEF DESCRIPTION OF THE DRAWINGS

FIG. 1 is a flowchart of a manufacturing method for a bonded substrate according to Embodiment 1 of the present invention.

FIG. 2 is a schematic sectional view illustrating steps of the manufacturing method for the bonded substrate according to Embodiment 1 of the present invention.

FIG. 3 is a schematic sectional view illustrating a state of a bonded interface of the bonded substrate after bonding in FIG. 2.

FIG. 4 is a schematic sectional view illustrating steps of a manufacturing method for a bonded substrate according to Embodiment 2 of the present invention.

FIG. 5 is a schematic sectional view illustrating a state of a bonded interface of the bonded substrate after bonding in FIG. 4.

### DETAILED DESCRIPTION OF THE PREFERRED EMBODIMENTS

A manufacturing method for a bonded substrate according to a first aspect includes: preparing a first substrate having a surface with a projected portion in a central region of the surface; preparing a second substrate; and bonding the first substrate and the second substrate using the projected portion as a bonding surface to be bonded to the second substrate.

According to a second aspect, in the manufacturing method for the bonded substrate according to the first aspect, an outer peripheral region of the bonding surface of the first substrate may be lower than the projected portion in the central region.

According to a third aspect, in the manufacturing method for the bonded substrate according to the first aspect, the first substrate may include a plurality of projected portions around the projected portion in the central region.

According to a fourth aspect, in the manufacturing method for the bonded substrate according to the third aspect, the projected portion in the central region may have a height not lower than heights of the plurality of the projected portions around the projected portion in the central region.

According to a fifth aspect, in the manufacturing method for the bonded substrate according to the third or fourth aspect, the first substrate may include a projected portion of the plurality of projected portions located on a concentric circle centered on the projected portion in the central region of the bonding surface.

With the above-described feature, since unevenness is formed concentrically, the spread of the bonding from the central region toward the outer peripheral region can be guided concentrically, thus enabling air to be purged out with the spread of the bonding. Hence the generation of voids can be suppressed.

According to a sixth aspect, in the manufacturing method for the bonded substrate according to the fifth aspect, the first substrate may be a substrate including an odd number of three or more projected portions inclusive of the projected portion in the central region and an even number of recessed portions.

According to a seventh aspect, in the manufacturing method for the bonded substrate according to any one of the first to sixth aspects, a difference between a height of the projected portion in the central region and a height of each of the recessed portions in the first substrate may be greater than a surface roughness of the bonding surface and may be 100 μm or smaller.

With the above-described feature, since the difference in height between the projected portion and the recessed portions is greater than the surface roughness of at least the bonding surface, an effect of causing the bonding to be started from the projected portion in the central region is obtained. Furthermore, since the difference in height between the projected portion and the recessed portions is 100 μm or smaller, the generation of voids in each recessed portion can be suppressed when the bonding spreads gradually from the projected portion in the central region toward the recessed portion in the peripheral region.

According to an eighth aspect, in the manufacturing method for the bonded substrate according to any one of the first to seventh aspects, the second substrate may have a bonding surface to be bonded to the first substrate and may include a projected portion formed in the bonding surface thereof at a position that is plane-symmetric with respect to the bonding surface of the first substrate.

With the above-described feature, when bonding the two substrates, the projected portion of the first substrate and the projected portion of the second substrate are first bonded to each other, and the bonding spreads gradually toward the outer peripheral region.

According to a ninth aspect, in the manufacturing method for the bonded substrate according to any one of the first to eighth aspects, the first substrate and the second substrate may be bonded by direct bonding.

According to a tenth aspect, in the manufacturing method for the bonded substrate according to any one of the first to ninth aspects, the first substrate may be a silicon substrate.

According to an eleventh aspect, in the manufacturing method for the bonded substrate according to any one of the first to tenth aspects, the first substrate may have a silicon oxide film on at least the bonding surface.

The manufacturing method for the bonded substrate according to each of embodiments of the present invention will be described below with reference to the accompanying drawings. It is to be noted that, in the drawings, substantially the same members are denoted by the same reference sings.

### Embodiment 1

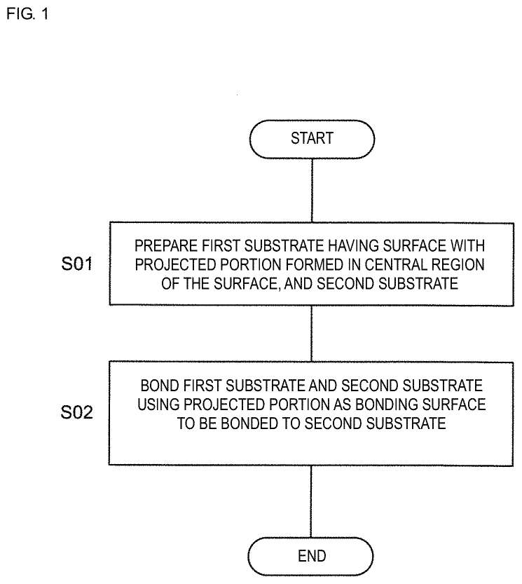

FIG. 1 is a flowchart of a manufacturing method for a bonded substrate according to Embodiment 1 of the present invention. As illustrated in FIG. 1, the manufacturing method for the bonded substrate according to this embodiment includes the following two steps.

(1) Prepare a first substrate having a surface with a projected portion formed in a central region of the first surface, and prepare a second substrate (e.g., a substrate preparation step).

(2) Bond the first substrate and the second substrate using the projected portion as a bonding surface (e.g., a substrate bonding step).

The steps of the manufacturing method for the bonded substrate will be described below.

### Substrate Preparation Step

In the substrate preparation step, the first substrate and the second substrate are first prepared.

### First Substrate

The first substrate is prepared as a substrate having a surface with a projected portion formed in a central region of the surface. In the first substrate, the surface with the projected portion formed in the central region serves as a bonding surface to be bonded to the second substrate. An outer peripheral region of the bonding surface of the first substrate may be lower than the projected portion in the central region. The number of the projected portions formed on the bonding surface is not limited to one. For example, the bonding surface may include, in addition to the projected portion formed in the central region, a plurality of projected portions formed around the projected portion in the central region. In such a case, the projected portion in the central region preferably has a height not lower than heights of the plurality of the projected portions formed around the projected portion in the central region. Moreover, in such a case, when the bonding is started, the first substrate and the second substrate are bonded gradually from a contact point between the projected portion formed in the central region of the bonding surface of the first substrate and a bonding surface of the second substrate toward a region around the projected portion formed in the central region. In another example, the first substrate may include, in addition to the projected portion formed in the central region, a projected portion formed on a concentric circle centered on the projected portion in the central region of the bonding surface. With the presence of the projected portion formed on the concentric circle centered on the projected portion in the central region of the bonding surface, it is ensured that a bonded region between the first substrate and the second substrate can be formed while spreading concentrically from the central region toward the outer peripheral region. Since air is purged out at that time, the generation of voids can be suppressed. In still another example, the first substrate may be prepared as a substrate including an odd number of three or more projected portions with inclusion of the projected portion in the central region and an even number of recessed portions.

Furthermore, in the first substrate, a difference between a height of the projected portion in the central region and a height of each recessed portion may be greater than a surface roughness Ra (for example, 0.1 nm to 0.2 nm) of the bonding surface and may be 100 μm or smaller. The difference in height is preferably 50 μm or smaller and more preferably 30 μm or smaller. The difference in height is even more preferably 5 μm or smaller and still even more preferably 0.5 μm or smaller. Due to that the difference between the height of the projected portion in the central region and the height of the recessed portion formed around the projected portion in the central region is greater than the surface roughness Ra of the bonding surface, the bonded region between the first substrate and the second substrate is caused to spread gradually from the projected portion in the central region toward the peripheral region when the bonding is started. In addition, due to that the difference between the height of the projected portion in the central region and the height of the recessed portion is 100 μm or smaller, the generation of voids in the recessed portion can be suppressed when the bonded region between the first substrate and the second substrate spreads from the projected portion in the central region toward the peripheral region.

Although, in this embodiment, the first substrate has the projected portion formed in the central region of the bonding surface as described above, the present invention is not limited to such a case and both the first substrate and the second substrate may include the projected portions formed in the central regions of the bonding surfaces.

### Second Substrate

The second substrate may have the bonding surface to be bonded to the first substrate and may include the projected portion formed in the bonding surface thereof at a position that is plane-symmetric with respect to the bonding surface of the first substrate. In such a case, when bonding the two substrates, the projected portion of the first substrate and the projected portion of the second substrate are first brought into contact with each other and the two substrates are then bonded. Hence the bonded region between the first substrate and the second substrate spreads gradually from the central region toward the outer peripheral region.

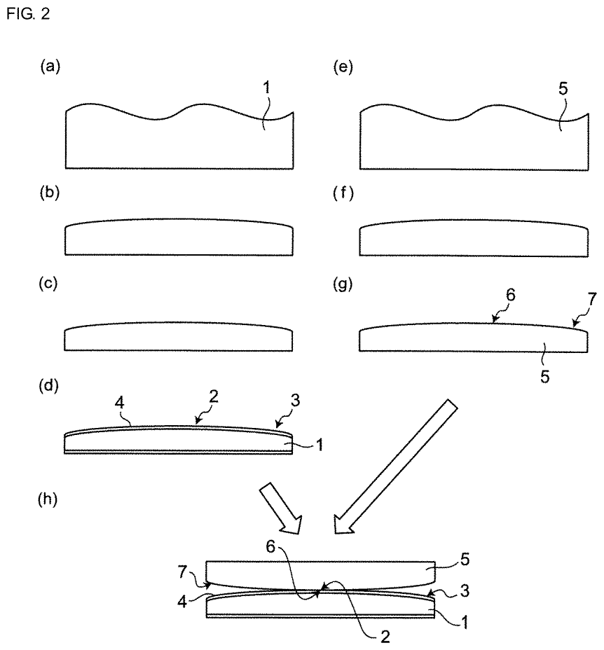

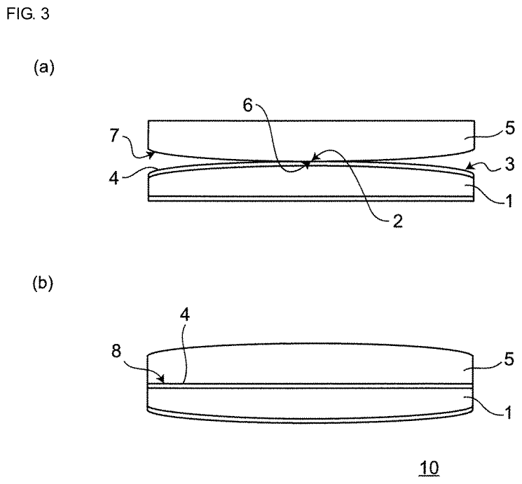

FIG. 2 is a schematic sectional view illustrating steps of the manufacturing method for the bonded substrate according to Embodiment 1 of the present invention. FIG. 3 is a schematic sectional view illustrating a state of a bonded interface of the bonded substrate after bonding in FIG. 2.

The substrate preparation step further includes, for example, not only a substrate placement step, a grinding step, and a chemical mechanical polishing (CMP) step, but also a thermal oxidation step when necessary.

The bonded substrate is used in, for example, a MEMS (Micro Electro Mechanical Systems) device. The first substrate serves as a handle substrate that is held in a manufacturing process when the MEMS device is manufactured, and the second substrate serves as a device substrate on or in which a structural part of the MEMS device is formed. In an example described below, it is assumed that the first substrate is a first silicon substrate serving as the handle substrate, and that the second substrate is a second silicon substrate serving as the device substrate. Moreover, in each of the two substrates, the projected portion is formed in the central region of the bonding surface.

### Substrate Placement Step

A first silicon substrate 1 serving as the handle substrate and a second silicon substrate 5 serving as the device substrate are prepared, and lower surfaces of the first silicon substrate 1 and the second silicon substrate 5 are each attracted to a chuck table of a grinder (FIGS. 2(a) and 2(e)). Usually, the first silicon substrate 1 and the second silicon substrate 5 have irregular uneven surfaces.

### Grinding Step

In the grinding step, projected portions and recessed portions are formed on and in the first silicon substrate 1 and the second silicon substrate 5. For example, by adjusting a tilt of the chuck table of the grinder, a projected portion 2 is formed in a central region of one surface of the first silicon substrate 1 when viewed from the side such that an outer peripheral region 3 has a lower height than the projected portion 2 (FIG. 2(b)). Similarly, by adjusting the tilt of the chuck table of the grinder, a projected portion 6 is formed in a central region of one surface of the second silicon substrate 5 when viewed from the side such that an outer peripheral region 7 has a lower height than the projected portion 6 (FIG. 2(f)).

### Chemical Mechanical Polishing (CMP) Step

In the chemical mechanical polishing step, the surfaces of the first silicon substrate 1 and the second silicon substrate 5 are polished into mirror-finished surfaces (FIGS. 2(c) and 2(g)). Here, shapes of the first silicon substrate 1 and the second silicon substrate 5, the shapes having been formed in the grinding step, can also be maintained by changing loads applied to the first silicon substrate 1 and the second silicon substrate 5. A polish amount is desirably set to a value at such a level as enabling a damaged layer formed in each of the first silicon substrate 1 and the second silicon substrate 5 in the grinding step to be removed and is also desirably set to a value at least at such a level as not impeding a polishing profile. The polish amount is preferably, for example, 500 nm to 3 μm.

### Thermal Oxidation Step

In the thermal oxidation step, a silicon oxide film 4 is formed on the surface of the first silicon substrate 1 serving as the handle substrate (FIG. 2(d)). The silicon oxide film 4 has a thickness of, for example, about 2 μm. In this embodiment, the silicon oxide film is formed only on the first silicon substrate 1.

### Substrate Bonding Step

Next, the first silicon substrate 1 including the projected portion 2 in the central region and the second silicon substrate 5 including the projected portion 6 in the central region, both the substrates having been prepared as described above, are bonded to each other (FIG. 2(h)). Prior to starting the bonding, positions of the projected portion 2 and the projected portion 6 may be adjusted for alignment. On that occasion, it is just required that part of the projected portion 2 and part of the projected portion 6 be substantially aligned, and both the projected portions may not need to be exactly aligned.

As illustrated in FIG. 3(a), at the start of the bonding between the first silicon substrate 1 and the second silicon substrate 5, the first silicon substrate 1 and the second silicon substrate 5 are in contact with each other only at the projected portion 2 and the projected portion 6. Thereafter, a bonded region between the first silicon substrate 1 and the second silicon substrate 5 gradually spreads from the central region to the outer peripheral region of each substrate. Upon completion of the bonding, as illustrated in FIG. 3(b), a bonded interface 8 is formed in the shape of a plane. On the other hand, the surfaces of the first silicon substrate 1 and the second silicon substrate 5 on the opposite side to the bonded interface 8 are deformed into shapes reflecting the shapes of the bonding surfaces of both the substrates before the bonding.

When the first silicon substrate 1 and the second silicon substrate 5 include the projected portions at positions that are plane-symmetric with respect to the bonded interface, the bonded interface 8 can be formed in the shape of a plane as described above.

The bonding may be direct bonding and may be performed in accordance with, for example, fusion bonding.

The fusion bonding can be implemented through, for example, the following steps.

a) At least one of the bonding surface of the first silicon substrate 1 and the bonding surface of the second silicon substrate 5 is hydrophilized, and a water film is formed.

b) The bonding surface of the first silicon substrate 1 and the bonding surface of the second silicon substrate 5 are temporarily bonded by a force of the water film.

c) The first silicon substrate 1 and the second silicon substrate 5 are heated in a temporarily bonded state.

d) When an ambient temperature reaches about 200° C. by heating, water and oxygen are purged out from a portion in which the bonding surface of the first silicon substrate 1 and the bonding surface of the second silicon substrate 5 are being bonded, whereby the bonding between the bonding surface of the first silicon substrate 1 and the bonding surface of the second silicon substrate 5 is realized with hydrogen bonding. As a result, bonding strength between the bonding surface of the first silicon substrate 1 and the bonding surface of the second silicon substrate 5 is increased.

e) During a period until the ambient temperature reaches about 600° C., voids generate in the portion in which the bonding surface of the first silicon substrate 1 and the bonding surface of the second silicon substrate 5 are being bonded because water and oxygen are purged out from the portion in which the bonding surface of the first silicon substrate 1 and the bonding surface of the second silicon substrate 5 are being bonded.

f) When the ambient temperature reaches about 1000° C., water and oxygen are diffused into Si and voids are no longer present in the portion in which the bonding surface of the first silicon substrate 1 and the bonding surface of the second silicon substrate 5 are being bonded. Hence the bonding strength between the bonding surface of the first silicon substrate 1 and the bonding surface of the second silicon substrate 5 is further increased.

In such a manner, the direct bonding between the first silicon substrate 1 and the second silicon substrate 5 is realized. A method for realizing the direct bonding is not limited to the above-described steps and may be selected as appropriate insofar as the direct bonding can be realized.

A bonded substrate 10 is obtained through the above-described steps.

According to the above-described manufacturing method for the bonded substrate, two substrates start to be bonded after the projected portion of the first substrate and the projected portion of the second substrate have contacted with each other, and the bonded region between the first substrate and the second substrate then spreads gradually from the central region toward the outer peripheral region of each substrate. Therefore, voids are less likely to generate in the bonded substrate. In addition, since the substrate itself has the above-described specific shape, there is no necessity of flexing or warping the substrate when bonded. As a result, a bonding apparatus with a complicated structure for flexing or warping the substrate is no longer required, and the bonded substrate can be manufactured by using a universal bonding apparatus.

### Embodiment 2

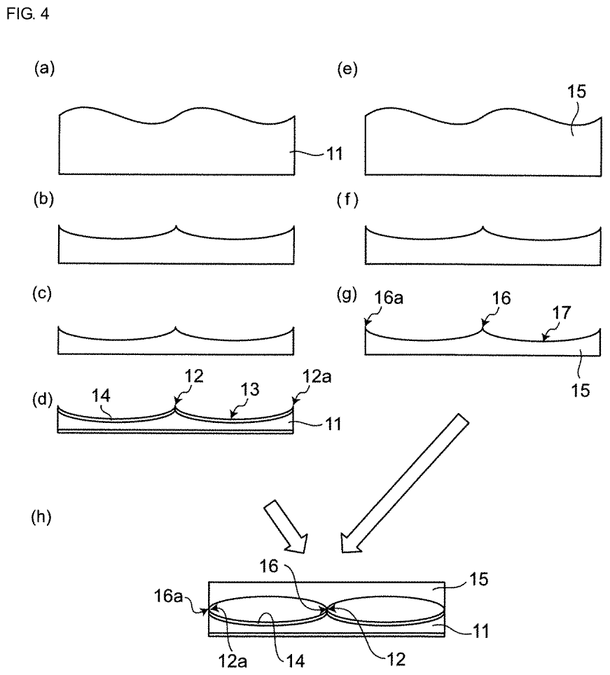

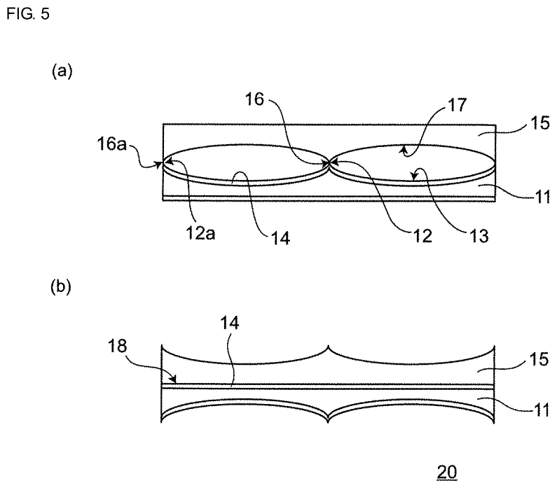

FIG. 4 is a schematic sectional view illustrating steps of a manufacturing method for a bonded substrate according to Embodiment 2 of the present invention. FIG. 5 is a schematic sectional view illustrating a state of a bonded interface of the bonded substrate after bonding in FIG. 4.

The manufacturing method for the bonded substrate according to Embodiment 2 of the present invention is different from the above-described manufacturing method for the bonded substrate according to Embodiment 1 in that a first silicon substrate 11 includes a projected portion 12 in a central region and a projected portion 12a in an outer peripheral region, and that a second silicon substrate 15 includes a projected portion 16 in a central region and a projected portion 16a in an outer peripheral region.

### Substrate Placement Step

The first silicon substrate 11 serving as the handle substrate and the second silicon substrate 15 serving as the device substrate are prepared, and lower surfaces of the first silicon substrate 11 and the second silicon substrate 15 are each attracted to the chuck table of the grinder (FIGS. 4(a) and 4(e)).

### Grinding Step

In the grinding step, projected portions and recessed portions are formed on and in the first silicon substrate 11 and the second silicon substrate 15. For example, by adjusting the tilt of the chuck table of the grinder, the projected portion 12 is formed in a central region of one surface of the first silicon substrate 11 and two projected portions 12a are formed in an outer peripheral region of the one surface when viewed from the side (FIG. 4(b)). Similarly, by adjusting the tilt of the chuck table of the grinder, the projected portion 16 is formed in a central region of one surface of the second silicon substrate 15 and two projected portions 16a are formed in an outer peripheral region of the one surface when viewed from the side (FIG. 4(f)). In other words, as illustrated in FIG. 4(b), the first silicon substrate 11 is a substrate that includes an odd number of the three or more projected portions 12 and 12a in the central region and at positions different from the central region when viewed from the side, and that includes an even number of recessed portions 13 when viewed from the side, the recessed portions 13 being concentric centered on the projected portion 12 in the central region when viewed from above. As illustrated in FIG. 4(f), the second silicon substrate 15 is a substrate that includes an odd number of the three or more projected portions 16 and 16a in the central region and at positions different from the central region when viewed from the side, and that includes an even number of recessed portions 17 when viewed from the side, the recessed portions 17 being concentric centered on the projected portion 12 in the central region when viewed from above.

### Chemical Mechanical Polishing (CMP) Step

In the chemical mechanical polishing step, the surfaces of the first silicon substrate 11 and the second silicon substrate 15 are polished into mirror-finished surfaces (FIGS. 4(c) and 4(g)). Here, shapes of the first silicon substrate 11 and the second silicon substrate 15, the shapes having been formed in the grinding step, can also be maintained by changing loads applied to the first silicon substrate 11 and the second silicon substrate 15. A polish amount is desirably set to a value at such a level as enabling a damaged layer formed in each of the first silicon substrate 11 and the second silicon substrate 15 in the grinding step to be removed and is also desirably set to a value at least at such a level as not impeding a polishing profile. The polish amount is preferably, for example, 500 nm 3 μm.

### Thermal Oxidation Step

In the thermal oxidation step, a silicon oxide film 14 is formed on the surface of the first silicon substrate 11 serving as the handle substrate (FIG. 4(d)). The silicon oxide film 14 has a thickness of, for example, about 2 μm. In this embodiment, the silicon oxide film is formed only on the first silicon substrate 11.

### Substrate Bonding Step

Next, the first silicon substrate 11 and the second silicon substrate 15 are bonded to each other (FIG. 4(h)). Prior to starting the bonding, respective positions of the projected portion 12 of the first silicon substrate 11 and the projected portion 16 of the second silicon substrate 15 and respective positions of the projected portions 12a of the first silicon substrate 11 and the projected portions 16a of the second silicon substrate 15 may be adjusted for alignment. On that occasion, it is just required that part of the projected portion 12 and part of the projected portion 16 be substantially aligned and that parts of the projected portions 12a and parts of the projected portion 16a be substantially aligned, and those projected portions may not need to be exactly aligned.

As illustrated in FIG. 5(a), at the start of the bonding between the first silicon substrate 11 and the second silicon substrate 15, the first silicon substrate 11 and the second silicon substrate 15 are in contact with each other only at the projected portion 12 and the projected portion 16 in the central regions and at the projected portions 12a and the projected portions 16a in the outer peripheral regions. Thereafter, a bonded region between the first silicon substrate 11 and the second silicon substrate 15 gradually spreads from the central region to the outer peripheral region of each substrate. Upon completion of the bonding, as illustrated in FIG. 5(b), a bonded interface 18 is formed in the shape of a plane. On the other hand, the surfaces of the first silicon substrate 11 and the second silicon substrate 15 on the opposite side to the bonded interface 18 are deformed into shapes reflecting the shapes of the bonding surfaces of both the substrates before the bonding.

A bonded substrate 20 is obtained through the above-described steps.

According to the above-described manufacturing method for the bonded substrate, two substrates start to be bonded after the projected portion in the central region of the first substrate and the projected portion in the central region of the second substrate have contacted with each other and the projected portions in the outer peripheral region of the first substrate and the projected portions in the outer peripheral region of the second substrate have contacted with each other, and the bonded region between the first substrate and the second substrate then spreads gradually from the central region toward the outer peripheral region of each substrate. Therefore, voids are less likely to generate in a central region and an outer peripheral region of the bonded substrate. In addition, since the substrate itself has the above-described specific shape, there is no necessity of flexing or warping the substrate when bonded. As a result, a bonding apparatus with a complicated structure for flexing or warping the substrate is no longer required, and the bonded substrate can be manufactured by using a universal bonding apparatus.

Moreover, bonding performance between the first substrate and the second substrate is increased by setting, in the grinding step and the chemical mechanical polishing step, at least one of a difference between a height of the projected portion in the central region and a height of the recessed portion around the projected portion in the central region and a difference between a height of the projected portion in the outer peripheral region and a height of the recessed portion around the projected portion in the outer peripheral region to be, for example, 0.5 μm or smaller.

It is to be noted that the present disclosure further includes appropriate combinations of optionally selected ones among the above-described embodiments and/or examples, and that those combinations can also provide similar advantageous effects to those obtained by the above-described embodiments and/or examples.

The present invention can be applied to a manufacturing method for a bonded substrate in which a first substrate and a second substrate are bonded to each other.

### REFERENCE SIGNS LIST

1 first silicon substrate
2 projected portion
3 outer peripheral region
4 silicon oxide film
5 second silicon substrate
6 projected portion
7 outer peripheral region
8 bonded interface
10 bonded substrate
11 first silicon substrate
12, 12a projected portion
13 recessed portion
14 silicon oxide film
15 second silicon substrate
16 projected portion
17 recessed portion
18 bonded interface
20 bonded substrate

1. A manufacturing method for a bonded substrate, the manufacturing method comprising:
preparing a first substrate having a surface with a projected portion in a central region of the surface;
preparing a second substrate; and
bonding the first substrate and the second substrate using the projected portion as a bonding surface to be bonded to the second substrate.

2. The manufacturing method for the bonded substrate according to claim 1, wherein an outer peripheral region of the bonding surface of the first substrate is lower than the projected portion in the central region.

3. The manufacturing method for the bonded substrate according to claim 1, wherein the first substrate includes a plurality of projected portions around the projected portion in the central region.

4. The manufacturing method for the bonded substrate according to claim 3, wherein the projected portion in the central region has a height not lower than heights of the plurality of the projected portions around the projected portion in the central region.

5. The manufacturing method for the bonded substrate according to claim 4, wherein the first substrate includes a projected portion of the plurality of projected portions located on a concentric circle centered on the projected portion in the central region of the bonding surface.

6. The manufacturing method for the bonded substrate according to claim 5, wherein the first substrate includes an odd number of three or more projected portions inclusive of the projected portion in the central region, and an even number of recessed portions.

7. The manufacturing method for the bonded substrate according to claim 3, wherein the first substrate includes a projected portion of the plurality of projected portions located on a concentric circle centered on the projected portion in the central region of the bonding surface.

8. The manufacturing method for the bonded substrate according to claim 7, wherein the first substrate includes an odd number of three or more projected portions inclusive of the projected portion in the central region, and an even number of recessed portions.

9. The manufacturing method for the bonded substrate according to claim 1, wherein the first substrate includes an even number of the recessed portions in the surface, and a difference between a height of the projected portion in the central region and a height of each of the recessed portions is greater than a surface roughness of the bonding surface and is 100 μm or smaller.

10. The manufacturing method for the bonded substrate according to claim 1, wherein the bonding surface of the first substrate is a first bonding surface, the protected portion is a first projected portion, and the second substrate has a second bonding surface that includes a second projected portion in the second bonding surface at a position that is plane-symmetric with respect to the first bonding surface of the first substrate.

11. The manufacturing method for the bonded substrate according to claim 10, wherein an outer peripheral region of the first bonding surface of the first substrate is lower than the first projected portion in the central region, and an outer peripheral region of the second bonding surface of the second substrate is lower than the second projected portion in the central region.

12. The manufacturing method for the bonded substrate according to claim 10, wherein the first substrate includes a first plurality of projected portions around the first projected portion in the central region, and the second substrate includes a second plurality of projected portions around the second projected portion in the central region.

13. The manufacturing method for the bonded substrate according to claim 12, wherein the first projected portion in the central region has a height not lower than heights of the first plurality of the projected portions around the first projected portion in the central region, and the second projected portion in the central region has a height not lower than heights of the second plurality of the projected portions around the second projected portion in the central region.

14. The manufacturing method for the bonded substrate according to claim 13, wherein the first substrate includes a projected portion of the first plurality of projected portions located on a concentric circle centered on the first projected portion in the central region of the first bonding surface, and the second substrate includes a projected portion of the second plurality of projected portions located on a concentric circle centered on the second projected portion in the central region of the second bonding surface.

15. The manufacturing method for the bonded substrate according to claim 14, wherein
the first substrate includes a first odd number of three or more projected portions inclusive of the first projected portion in the central region, and an even number of first recessed portions, and
the second substrate includes a second odd number of three or more projected portions inclusive of the second projected portion in the central region, and an even number of second recessed portions.

16. The manufacturing method for the bonded substrate according to claim 12, wherein the first substrate includes a projected portion of the first plurality of projected portions located on a concentric circle centered on the first projected portion in the central region of the first bonding surface, and the second substrate includes a projected portion of the second plurality of projected portions located on a concentric circle centered on the second projected portion in the central region of the second bonding surface.

17. The manufacturing method for the bonded substrate according to claim 16, wherein
the first substrate includes a first odd number of three or more projected portions inclusive of the first projected portion in the central region, and an even number of first recessed portions, and
the second substrate includes a second odd number of three or more projected portions inclusive of the second projected portion in the central region, and an even number of second recessed portions.

18. The manufacturing method for the bonded substrate according to claim 1, wherein the first substrate and the second substrate are bonded by direct bonding.

19. The manufacturing method for the bonded substrate according to claim 1, wherein the first substrate is a silicon substrate.

20. The manufacturing method for the bonded substrate according to claim 1, wherein the first substrate has a silicon oxide film on at least the bonding surface.
